(19) United States
(12) Patent Application Publication
(10) Pub. No.: US 2014/0354112 A1
(43) Pub. Date: Dec. 4, 2014

(54) PIEZOELECTRIC RESONATORS FOR REDUCTION OF NOISE AND VIBRATION IN VEHICLE COMPONENTS

(71) Applicant: GM GLOBAL TECHNOLOGY OPERATIONS LLC, Detroit, MI (US)

(72) Inventor: Teo L. Rocha, Indaiatuba (BR)

(21) Appl. No.: 13/907,273

(22) Filed: May 31, 2013

(51) Int. Cl. H03H 9/17

(52) U.S. Cl. CPC H03H 9/17
USPC 310/319

(57) ABSTRACT

Disclosed herein is a piezoelectric resonator for damping noise from a vehicle component. The piezoelectric resonator includes a first piezoceramic material having a first electrode, the first piezoceramic material disposed at a first location on one side of the vehicle component and a second piezoceramic material having a second electrode, the second piezoceramic material disposed at a second location on an opposing side of the vehicle component, wherein the first location is opposite the second location. The piezoelectric resonator also includes a shunt circuit comprising a resistor and an inductor, the shunt circuit connected to the first electrode and the second electrode in series. The shunt circuit is configured to dissipate energy from vibration experienced by the vehicle component.

### BACKGROUND

The subject invention relates generally to noise reduction in vehicle components for vehicles, and more specifically to systems and methods for reducing noise and vibration in vehicle components using piezoelectric resonators.

Noise in a vehicle is generally caused by the vibration of various vehicle components, such as the dash board, door panels, roof, or the like. For example, vibrations caused by the engine may cause a dash panel to vibrate leading to noise in the vehicle cabin. Currently, the control of such noise and vibrations is performed by placing a viscoelastic or other suitable damping material on the vehicle component. While acoustic treatments based on viscoelastic damping materials can effectively and economically control noise and vibration, viscoelastic damping materials have a high density, which can lead to significant increases in the overall mass of the sound insulation system.

### SUMMARY OF THE INVENTION

In one exemplary embodiment, a method for reducing noise and vibration in a vehicle component includes affixing a first piezoceramic material to a location on one side of the vehicle component and affixing a second piezoceramic material to the location on an opposing side of the vehicle component. The method also includes connecting the first and the second piezoceramic materials in series to a shunt circuit having a resistor element wherein the shunt circuit is configured to perform in broadband, dissipating energy from several modes of vibration experienced by the vehicle component.

In another exemplary embodiment, a piezoelectric resonator for damping noise from a vehicle component includes a first piezoceramic material having a first electrode, the first piezoceramic material disposed at a first location on one side of the vehicle component. The piezoelectric resonator also includes a second piezoceramic material having a second electrode, the second piezoceramic material disposed at a second location on an opposing side of the vehicle component, wherein the first location is opposite the second location. The piezoelectric resonator further includes a shunt circuit comprising a resistor and an inductor, the shunt circuit connected to the first electrode and the second electrode in series. The shunt circuit is configured to dissipate energy from a specific mode of vibration experienced by the vehicle component. Due to the piezoelectric material inherent capacitance, the resulting electrical network is equivalent to a Resistor-Inductor-Capacitor (R-L-C) circuit performing as a tuned vibration absorber.

In yet another exemplary embodiment, a piezoelectric resonator for damping noise from a vehicle component includes a first piezoceramic material having a first electrode, the first piezoceramic material disposed at a first location on one side of the vehicle component that experiences a strain. The piezoelectric resonator also includes a second piezoceramic material having a second electrode, the second piezoceramic material disposed at a second location on an opposing side of the vehicle component, wherein the first location is opposite the second location and a shunt circuit comprising a resistor and an active inductor, the shunt circuit connected to the first electrode and the second electrode in series. The active inductor comprising a plurality of resistors, an operational amplifier, a capacitor and a variable resistor, wherein an inductance of the active inductor is adjustable by adjusting the variable resistor. The shunt circuit is configured to dissipate energy from vibration experienced by the vehicle component.

The above features and advantages and other features and advantages of the invention are readily apparent from the following detailed description of the invention when taken in connection with the accompanying drawings.

### BRIEF DESCRIPTION OF THE DRAWINGS

Other features, advantages and details appear, by way of example only, in the following detailed description of embodiments, the detailed description referring to the drawings in which:

FIG. 1 is a diagram of a piezoelectric resonator in accordance with an exemplary embodiment;

FIG. 2 is a flow diagram of a method for reducing noise and vibrations in vehicle components with a piezoelectric resonator in accordance with an exemplary embodiment;

FIG. 3 is a circuit diagram of a shunt circuit for use with a piezoelectric resonator in accordance with an exemplary embodiment; and

FIG. 4 is a graph illustrating the performance of a piezoelectric resonator in damping noise from a vehicle component in accordance with an exemplary embodiment.

### DESCRIPTION OF THE EMBODIMENTS

The following description is merely exemplary in nature and is not intended to limit the present disclosure, its application or uses.

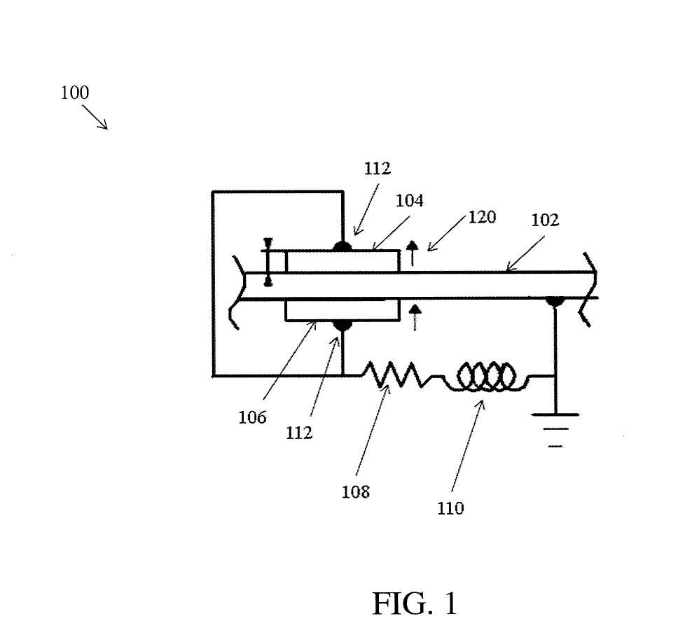

Referring now to FIG. 1, a piezoelectric resonator 100 in accordance with an exemplary embodiment is shown. The piezoelectric resonator 100 includes a vehicle component 102 having a first piezoceramic material 104 and a second piezoceramic material 106 disposed on opposite sides of the vehicle component 102. In exemplary embodiments, the vehicle component 102 may be a dash panel, a floor panel or the like. The first piezoceramic material 104 and the second piezoceramic material 106 are connected in series to a resistor 108 and an inductor 110. The first piezoceramic material 104 and the second piezoceramic material 106 are configured to act as mechanical vibration absorbers designed to attenuate vibration in the vehicle component 102.

In exemplary embodiments, the piezoceramic materials 104, 106 may be three-dimensional devices poled along one axis. The piezoceramic materials 104, 106 may include electrodes 112 that are disposed on an outer surface, which is the surface opposite the vehicle component 102. As a voltage difference is applied across the electrodes 112 a strain is produced in a direction normal to the outer surface. In exemplary embodiments, the piezoceramic materials 104, 106 are wired to produce opposite fields in the first and second piezoceramic materials 104, 106, thus causing the first piezoceramic material 104 to contract as the second piezoceramic material 106 expands, producing a moment 120 in the vehicle component 102. Conversely, when the vehicle component 102 is strained, an electric field is generated in the piezoceramic materials 104, 106. In exemplary embodiments, a shunt circuit including the resistor 108 and an inductor 110 can be used as a broadband resonator to dissipate energy from all modes of vibration experienced by the vehicle component 102. In another embodiment, an inherent capacitance of the piezoceramic materials 104, 106 can be combined with the resistor 108 and the inductor 110 to form a shunt circuit configured for optimal performance at specific electrical resonant frequency.

In exemplary embodiments, optimum resistor and inductor values, Rₒₚₜ and Lₒₚₜ, respectively, for a shunt circuit can be calculated using the following procedures. First, a generalized electromechanical coupling coefficient, K, is calculated based on the natural frequencies (in rad/s) of the piezoelectric resonator when the system is in an open condition (ωₒ) and short circuited condition (ωₛ):

K=\sqrt{ωₒ²−ωₛ²/ωₛ²}

Next, the electromechanical coupling coefficient, k, and the pre-bonded piezoceramic capacitance, C^{T}, are measured, in order to derive the piezoceramic capacitance at constant strain, C^{S}:

C^{S}=(1−k²)C^{T}.

The optimal circuit damping, rₒₚₜ, can be calculated by:

rₒₚₜ=(K\sqrt{2})/(1+K²).

The optimal series resistance can be calculated by:

Rₒₚₜ=rₒₚₜ/C^{S}ωₒ

and the optimal series inductance can be calculated by setting the electrical frequency equal to the short-circuit frequency:

$${L}_{opt} = \frac{1}{{C}^{S} {ω}_{s}^{2}} ;$$

$$where$$

$${ω}_{s} = {ω}_{e} .$$

In exemplary embodiments, a plurality of piezoelectric resonators 100 may be disposed across the surface of the vehicle component 102. In exemplary embodiments, the number and location of the piezoelectric resonators 100 on a given vehicle component 102 are selected to minimize the noise created by the vibration of the vehicle component 102. In addition, the size of the piezoceramic materials 104, 106 used in the piezoelectric resonators 100 may also be selected to minimize the noise created by the vibration of the vehicle component 102. In one embodiment, a plurality of piezoelectric resonators 100 with small piezoceramic materials 104, 106 may be disposed on the vehicle component 102. In another embodiment, a single piezoelectric resonator 100 with large piezoceramic materials 104, 106 may be disposed on the vehicle component 102.

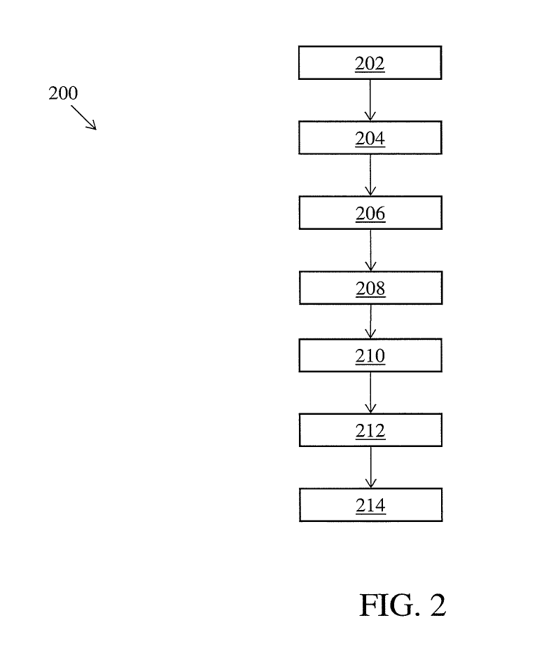

Referring now to FIG. 2, a flow diagram of a method 200 for reducing noise and vibrations in a vehicle component with a piezoelectric resonator in accordance with an exemplary embodiment is shown. The method 200 includes identifying a vehicle component that is experiencing vibration, as shown at block 202. Next, at block 204, the method 200 includes identifying one or more locations on the vehicle component that is experiencing a relatively large amount of strain, compared to other locations on the vehicle component. Once these locations are identified, the method 200 includes affixing a piezoceramic material to either side of the identified locations and connecting the first and second piezoceramic materials with electrodes to form a piezoelectric resonator, at block 206. At block 208, the method 200 includes measuring a frequency of the piezoelectric resonator with open and short circuited terminals. Next, at block 210, the method 200 includes calculating an optimal inductance and an optimal resistance based on the properties of the piezoelectric materials and the measured frequencies with open and short circuited terminals. At block 212, the method 200 includes tuning the circuit values of the resistor and inductor to the calculated optimal values. Finally, at block 214, the method includes grounding the piezoelectric resonator and connecting the circuit terminals to the exterior electrode surfaces of the piezoceramic pairs.

In exemplary embodiments, the choice of design parameters, such as the placement for the piezoceramic materials and the optimal electrical circuit values, can be determined using finite element simulation, theoretical analysis, experimental analysis, or any combination thereof. In one embodiment, measurements of sound transmission loss and modal analyses can be conducted to compare the efficiency of the piezoelectric resonator to the use of conventional damping materials.

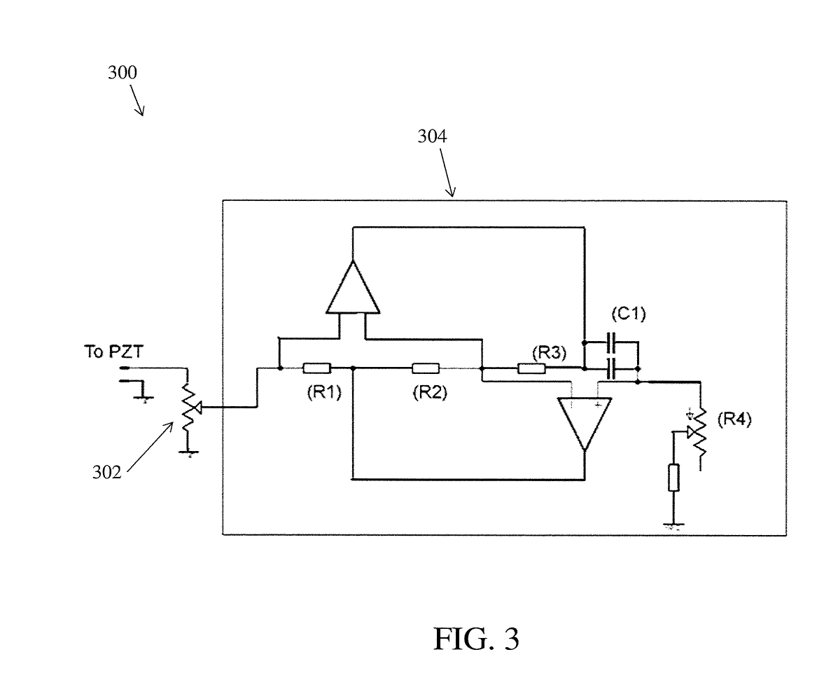

Referring now to FIG. 3, a circuit diagram of a shunt circuit 300 for use with a piezoelectric resonator in accordance with an exemplary embodiment is shown. As illustrated the shunt circuit 300 includes a resistor 302 and an inductor 304. In exemplary embodiments, the resistor 302 is a variable resistor that can be set to Rₒₚₜ and the inductor 304 is a synthetic inductor created by an operational amplifier. The operational amplifier includes four resistors R₁, R₂, R₃, R₄ and a capacitor C₁, the value of R₄ can be adjusted to create a desired inductance. The inductance value can be determined by:

$${L}_{opt} = \frac{{R}_{1} {R}_{3} {R}_{4}}{{R}_{2}} {C}_{1}$$

and the damping can be adjusted through the variable resistor 302.

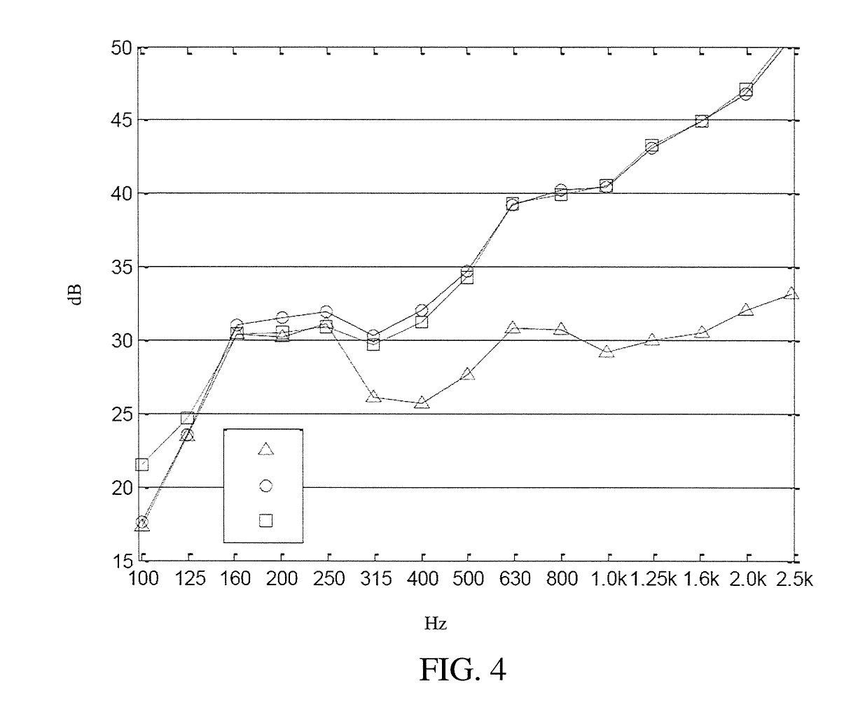

Referring now to FIG. 4, a graph illustrating the performance of a piezoelectric resonator in damping noise from a vehicle component in accordance with an exemplary embodiment is shown. The graph illustrates the sound transmission loss of a tested vehicle component at various frequencies. In addition, the graph illustrates the performance of the vehicle component with no damping (Δ), the vehicle component with viscoelastic patches (◯), and the vehicle component with piezoelectric resonators (□) as described in detail herein. As illustrated the piezoelectric resonators provide the most noise and vibration benefits below 160 Hz (3.0 dB gain in sound transmission loss at 100 Hz) and from 160 Hz to 400 Hz the sound transmission loss with viscoelastic material is 1.0 dB higher on average. In addition to the benefits of the increased reduction in noise, the piezoceramic materials used were approximately 70% lighter than conventional viscoelastic patches, which can result in increased fuel efficiency of the automobile.

In contrast to the conventional passive damping techniques using viscoelastic materials, the capability of piezoceramics, such as Lead Zirconate Titanate (PZT), to transform mechanical energy into electrical energy, and vice versa, allows the design of active and semi-passive damping systems. In exemplary embodiments, the shunt circuit coupled to the piezoelectric resonator may be configured to provide semi-passive or active damping control of the piezoelectric resonator. In active vibration control damping systems, a feedback controller is used to cancel the vibration in a certain region of the structure and in a defined frequency range. In this case, the performance of the controller is limited by the use of anti-aliasing filters and high-voltage amplifiers to drive the actuators. Semi-passive control techniques, as discussed in more detail above, convert mechanical energy into electrical energy and then dissipate the electrical energy in the form of heating a resistor. Electrical elements along with the capacitance of the piezoceramic materials can form a resonant circuit, tuned to a specific resonance frequency of the vibrating structure, resulting in vibration reduction for that specific mode.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The flow diagrams depicted herein are just one example. There may be many variations to this diagram or the steps (or operations) described therein without departing from the spirit of the disclosure. For instance, the steps may be performed in a differing order or steps may be added, deleted or modified. All of these variations are considered a part of the claimed disclosure.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed, but that the invention will include all embodiments falling within the scope of the application.

What is claimed is:

1. A method for reducing noise and vibration in a vehicle component comprises:
affixing a first piezoceramic material to a location on one side of the vehicle component;
affixing a second piezoceramic material to the location on an opposing side of the vehicle component; and
connecting the first and second piezoceramic material in series to a shunt circuit having a resistor and an inductor;
wherein the shunt circuit is configured to dissipate energy from vibration experienced by the vehicle component.

2. The method of claim 1, wherein the inductor is a synthetic inductor comprising an operational amplifier and a variable resistor.

3. The method of claim 1, further comprising calculating an optimal inductance and an optimal resistance based on the properties of the first and second piezoelectric materials, a measured open circuit frequency, and a measured short frequency.

4. The method of claim 3, wherein the resistor has a value of the optimal resistance and the inductor has a value of the optimal inductance.

5. The method of claim 1, wherein the location is selected to be a portion of the vehicle component that experiences a strain.

6. The method of claim 5, wherein the portion of the vehicle component is determined by finite element simulation.

7. A piezoelectric resonator for damping noise from a vehicle component comprising:
a first piezoceramic material having a first electrode, the first piezoceramic material disposed at a first location on one side of the vehicle component;
a second piezoceramic material having a second electrode, the second piezoceramic material disposed at a second location on an opposing side of the vehicle component, wherein the first location is opposite the second location; and
a shunt circuit comprising a resistor and an inductor, the shunt circuit connected to the first electrode and the second electrode in series;
wherein the shunt circuit is configured to dissipate energy from vibration experienced by the vehicle component.

8. The piezoelectric resonator of claim 7, wherein the inductor is a synthetic inductor comprising an operational amplifier and a variable resistor.

9. The piezoelectric resonator of claim 7, wherein an optimal inductance and an optimal resistance are calculated based on the properties of the first and second piezoelectric materials, a measured open circuit frequency, and a measured short frequency.

10. The piezoelectric resonator of claim 9, wherein the resistor has a value of the optimal resistance and the inductor has a value of the optimal inductance.

11. The piezoelectric resonator of claim 7, wherein the first location is selected to be a portion of the vehicle component that experiences a strain.

12. The piezoelectric resonator of claim 11, wherein the portion of the vehicle component is determined by finite element simulation.

13. A piezoelectric resonator for damping noise from a vehicle component comprising:
a first piezoceramic material having a first electrode, the first piezoceramic material disposed at a first location on one side of the vehicle component that experiences a strain;
a second piezoceramic material having a second electrode, the second piezoceramic material disposed at a second location on an opposing side of the vehicle component, wherein the first location is opposite the second location; and
a shunt circuit comprising a resistor and an active inductor, the shunt circuit connected to the first electrode and the second electrode in series;
the active inductor comprising a plurality of resistors, an operational amplifier, a capacitor and a variable resistor, wherein an inductance of the active inductor is adjustable by adjusting the variable resistor;
wherein the shunt circuit is configured to dissipate energy from vibration experienced by the vehicle component.

14. The piezoelectric resonator of claim 13, wherein an optimal inductance and an optimal resistance are calculated based on the properties of the first and second piezoelectric materials, a measured open circuit frequency, and a measured short frequency.

15. The piezoelectric resonator of claim 14, wherein the resistor has a value of the optimal resistance and the inductor has a value of the optimal inductance.

16. The piezoelectric resonator of claim 13, wherein the first location on the vehicle component is determined by finite element simulation.
